(19) United States
(12) Patent Application Publication
(10) Pub. No.: US 2016/0149113 A1
(43) Pub. Date: May 26, 2016

(54) PIEZOELECTRIC ACTUATOR AND LENS MODULE INCLUDING THE SAME

(71) Applicant: SAMSUNG ELECTRO-MECHANICS CO., LTD., Suwon-si (KR)

(72) Inventors: Jeong Suong Yang, Suwon-si (KR); Jung Won Lee, Suwon-si (KR); Jong Beom Kim, Suwon-si (KR); Yun Sung Kang, Suwon-si (KR); In Young Kang, Suwon-si (KR)

(73) Assignee: SAMSUNG ELECTRO-MECHANICS CO., LTD., Suwon-si (KR)

(21) Appl. No.: 14/939,368

(22) Filed: Nov. 12, 2015

(30) Foreign Application Priority Data
Nov. 21, 2014 (KR) 10-2014-0163325

(51) Int. Cl. H01L 41/047; H01L 41/18; G02B 7/08; H01L 41/09

(52) U.S. Cl. CPC H01L 41/047; H01L 41/09; H01L 41/18; G02B 7/08

(57) ABSTRACT

A piezoelectric actuator includes a piezoelectric element, a first electrode disposed on a first surface of the piezoelectric element, and a second electrode disposed on a second surface of the piezoelectric element. One or more first grooves extending in a first direction of the piezoelectric element are formed in the first electrode.

### CROSS-REFERENCE TO RELATED APPLICATION(S)

This application claims the benefit under 35 USC 119(a) of Korean Patent Application No. 10-2014-0163325 filed on Nov. 21, 2014, in the Korean Intellectual Property Office, the entire disclosure of which is incorporated herein by reference for all purposes.

### BACKGROUND

1. Field

This application relates to a piezoelectric actuator capable of adjusting a focal length of a lens, and a lens module including the same.

2. Description of Related Art

A piezoelectric actuator may be applied to apparatuses for use in various fields. For example, the piezoelectric actuator may be mounted in a lens module to be used to adjust a focal length of a lens. Particularly, since the installation space of the piezoelectric actuator is not limited, the piezoelectric actuator may be easily mounted in a small lens module.

During manufacturing of such a piezoelectric actuator, defects such as pores may be formed. Such defects may decrease driving reliability of the piezoelectric actuator. For example, a defective piezoelectric actuator may have difficulty in precisely adjusting the focal length of the lens.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a piezoelectric actuator includes a piezoelectric element; a first electrode disposed on a first surface of the piezoelectric element; and a second electrode disposed on a second surface of the piezoelectric element; wherein one or more first grooves extending in a first direction of the piezoelectric element are formed in the first electrode.

One or more second grooves extending in a second direction of the piezoelectric element may be formed in the first electrode.

The first and second grooves may have different dimensions.

One or more third grooves extending in the first direction of the piezoelectric element may be formed in the second electrode.

The first and third grooves may have different dimensions.

One or more fourth grooves extending in a second direction of the piezoelectric element may be formed in the second electrode.

The first and fourth grooves may have different dimensions.

The piezoelectric element may include a manganese oxide.

In another aspect, a lens module includes a plurality of connecting portions connecting a fixed portion and a lens support portion to each other; and piezoelectric actuators disposed in or on the plurality of connecting portions and configured to deform the connecting portions to change a position of the lens support portion relative to the fixed portion; wherein each of the piezoelectric actuators includes a piezoelectric element; a first electrode disposed on a first surface of the piezoelectric element and in which one or more first grooves extending in a first direction of the piezoelectric element are formed; and a second electrode disposed on a second surface of the piezoelectric element.

One or more second grooves extending in a second direction of the piezoelectric element may be formed in the first electrode.

The first and second grooves may have different dimensions.

One or more third grooves extending in the first direction of the piezoelectric element may be formed in the second electrode.

The first and third grooves may have different dimensions.

One or more fourth grooves extending in a second direction of the piezoelectric element may be formed in the second electrode.

The first and fourth grooves may have different dimensions.

The piezoelectric element may include a manganese oxide.

In one general aspect, a piezoelectric actuator includes a piezoelectric element; a first electrode disposed on the piezoelectric element; and a second electrode disposed on the piezoelectric element; wherein either one or both of the first electrode and the second electrode are configured to cause the piezoelectric actuator to have areas having different current resistance values.

One or more grooves may be formed in the either one or both of the first electrode and the second electrode to cause the piezoelectric actuator to have the areas having different current resistance values.

The one or more grooves may include a plurality of grooves having different dimensions.

The one or more grooves may include a plurality of grooves extending in different directions of the piezoelectric actuator.

Other features and aspects will be apparent from the following detailed description, the drawings, and the claims.

### BRIEF DESCRIPTION OF DRAWINGS

FIG. 1 is a perspective view of a first example of a piezoelectric actuator.

FIG. 2 is a perspective view of a second example of a piezoelectric actuator.

FIG. 3 is a perspective view of a modified form of the second example of the piezoelectric actuator in FIG. 2.

FIG. 4 is a perspective view of a third example of a piezoelectric actuator.

FIG. 5 is a perspective view of a modified form of the third example of the piezoelectric actuator in FIG. 4.

FIG. 6 is a perspective view of another modified form of the third example of the piezoelectric actuator in FIG. 4.

FIG. 7 is a perspective view of a fourth example of a piezoelectric actuator.

FIG. 8 is a cross-sectional view of the fourth example of the piezoelectric actuator in FIG. 7 taken along the line VIII-VIII in FIG. 7.

FIG. 9 is a cross-sectional view of the fourth example of the piezoelectric actuator in FIG. 7 taken along the line IX-IX in FIG. 7.

FIG. 10 is a plan view of an example of a lens module.

FIG. 11 is an example of a cross-sectional view of the example of the lens module in FIG. 10 taken along the line XI-XI in FIG. 10.

FIG. 12 is another example of a cross-sectional view of the example of the lens module in FIG. 10 taken along the line XII-XII in FIG. 12.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

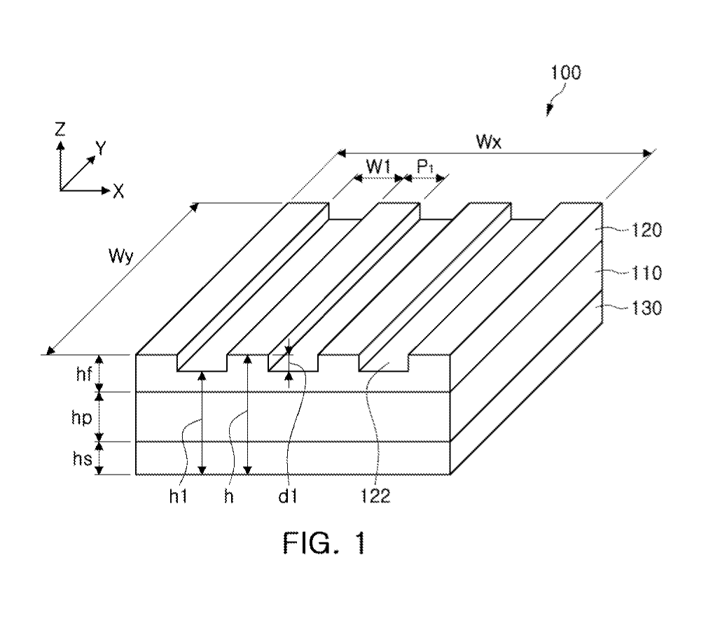

FIG. 1 is a perspective view of a first example of a piezoelectric actuator.

A piezoelectric actuator 100 in FIG. 1 includes a piezoelectric element 110, a first electrode 120, and a second electrode 130. In this example, the piezoelectric actuator 100 is a structure in which the second electrode 130, the piezoelectric element 110, and the first electrode 120 are sequentially stacked in the order listed. That is, the piezoelectric element is stacked on the second electrode 130, and the first electrode 120 is stacked on the piezoelectric element 110.

The piezoelectric element 110 may be formed of a ceramic material. For example, the piezoelectric element 110 may be formed of lead zirconate titanate (PZT) ceramic. The piezoelectric element 110 may be formed of a material containing a manganese oxide (MnO₂). For example, the piezoelectric element 110 may be formed of a composite oxide containing manganese. The piezoelectric element 110 may include manganese compounds affixed to a surface thereof. For example, manganese oxide compounds may be affixed to the surface of the piezoelectric element 110.

In the piezoelectric element 110 configured as described above, a phase change may be generated through high-temperature heat generation. In addition, the piezoelectric element 110 may self-heal internal defects through the phase change. For example, internal defects of the piezoelectric element 110 may be filled with surrounding particles.

The piezoelectric element 110 has a predetermined height hp. The height hp is determined depending on the purpose of a device in which the piezoelectric actuator 100 is mounted. For example, in a case in which a large driving force is required, the height hp of the piezoelectric element 110 is increased. As another example, in a case in which a small driving force is required, the height hp of the piezoelectric element 110 is decreased.

The first electrode 120 is disposed on a first surface of the piezoelectric element 110. In the example in FIG. 1, the first electrode 120 is disposed on an upper surface of the piezoelectric element 110. The first electrode 120 has depressions. In the example in FIG. 1, a plurality of first grooves 122 are formed in a surface of the first electrode 120.

The first grooves 122 extend in a first direction (the Y-axis direction in FIG. 1) of the piezoelectric element 110. In the example in FIG. 1, a length of the first grooves 122 is the same as a length Wy of the piezoelectric element 110 in a first direction.

The first grooves 122 have a first depth d1 and a first width W1. The first depth d1 is smaller than a height hf of the first electrode 120. For example, the first depth d1 may be smaller than ½ of the height hf of the first electrode 120.

The first width W1 of the first grooves 122 is smaller than a length Wx of the first electrode 120 in a second direction. In addition, a space P1 between the first grooves 122 may be the same as or different from the width W1 of the first grooves 122.

The second electrode 130 is disposed on a second surface of the piezoelectric element 110. In the example in FIG. 1, the second electrode 130 is disposed on a lower surface of the piezoelectric element 110. The second electrode 130 has a predetermined height hs. For example, the second electrode 130 may have a height that is substantially the same as or similar to the height hf of the first electrode 120.

The piezoelectric actuator 100 formed as described above has portions having different heights. For example, the piezoelectric actuator 100 has a height h in portions in which the first grooves 122 are not formed, and has a first height h1 in portions in which the first grooves 122 are formed.

A high-temperature heat generation phenomenon occurs in the portions in which the first grooves 122 are formed. For example, since the portions in which the first grooves 122 are formed have a high current resistance value relative to surrounding portions in which the first grooves 122 are not formed due to having a height lower than a height of the surrounding portions, when a current is supplied to the piezoelectric actuator 100, the high-temperature heat generation phenomenon occurs in the portions in which the first grooves 122 are formed due to the high current resistance value.

The high-temperature heat generation phenomenon causes a phase change in the portions in which the first grooves 122 are formed. For example, a phase change phenomenon occurs in partial regions of the piezoelectric element 110 adjacent to the first grooves 122. A phase change of the piezoelectric element 110 induces or generates a mechanism compensating for defects included in the piezoelectric element 110. Therefore, the piezoelectric actuator 100 may achieve driving reliability regardless of whether defects are present in the piezoelectric element 110.

Next, other examples of piezoelectric actuators will be described. For reference, in the following descriptions of the other examples, components that are the same as those of the piezoelectric actuator in FIG. 1 will be denoted by the same reference numerals, and descriptions thereof will be omitted.

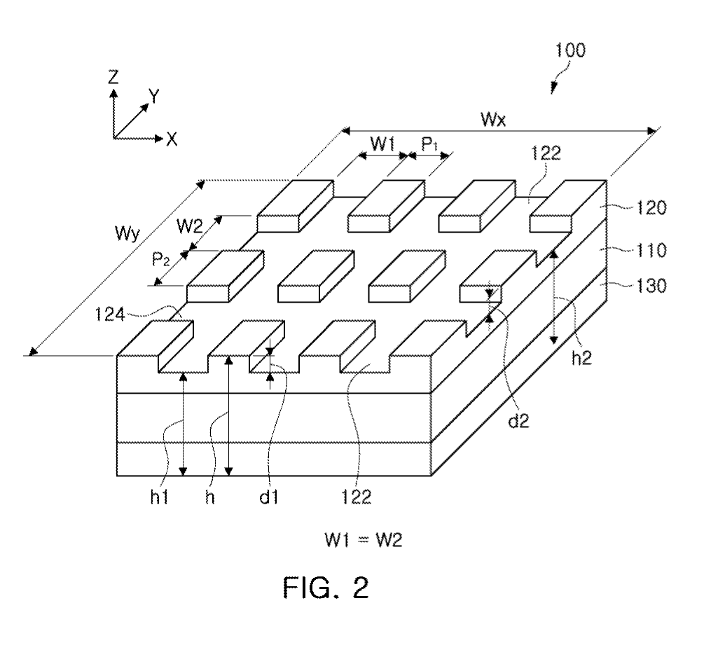

FIG. 2 is a perspective view of a second example of a piezoelectric actuator.

A piezoelectric actuator 100 in FIG. 2 has a first electrode 120 having a different form than the example of the piezoelectric actuator 100 in FIG. 1. In this example, first and second grooves 122 and 124 extending in directions perpendicular to one another are formed in the first electrode 120.

The first grooves 122 are formed in a first direction (the Y-axis direction in FIG. 2) of the piezoelectric actuator 100. The first grooves 122 have a first width W1 and a first depth d1. The first grooves 122 reduce a height of portions of the piezoelectric actuator 100. For example, the piezoelectric actuator 100 has a height h in portions in which the first grooves 122 are not formed, and has a first height h1 in portions in which the first grooves 122 are formed. The first height h1 is lower than the height h.

The second grooves 124 are formed in a second direction (the X-axis direction in FIG. 2) of the piezoelectric actuator 100. The second grooves 124 have a second width W2 and a second depth d2.

The second width W2 is smaller than a length Wy of the piezoelectric actuator 100 in the first direction, and the second depth d2 is smaller than a height hf of the first electrode 120. The second width W2 may be the same as or similar to the first width W1.

The second depth d2 may be the same as or similar to the first depth d1.

The second grooves 124 reduce a height of portions of the piezoelectric actuator 100. For example, a second height h2 of portions in which the second grooves 124 are formed is lower than the height h of portions in which the second grooves 124 are not formed.

In the piezoelectric actuator 100 having the first electrode 120 with the structure described above, high-temperature heat generation and phase change phenomena occur in regions in which the first and second grooves 122 and 124 are formed. Therefore, defects formed in the piezoelectric element 110 may be more effectively cured. Consequently, driving reliability of the piezoelectric actuator 100 may be achieved.

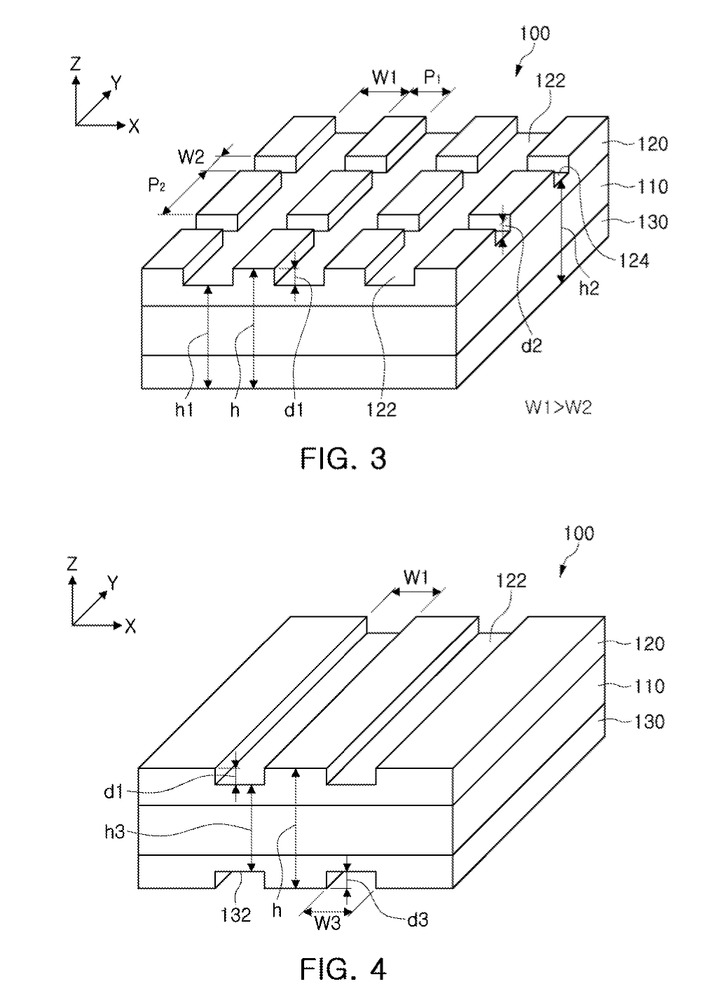

FIG. 3 is a perspective view of a modified form of the second example of the piezoelectric actuator in FIG. 2.

The piezoelectric actuator 100 in FIG. 2 may be modified into a form illustrated in FIG. 3. For example, a width W1 of the first grooves 122 is larger than a width W2 of the second grooves 124. However, a dimension relationship between the first and second grooves 122 and 124 is not limited to this example. As another example, a width W1 of the first grooves 122 may be smaller than a width W2 of the second grooves 124.

FIG. 4 is a perspective view of a third example of a piezoelectric actuator.

The piezoelectric actuator 100 in FIG. 4 has a second electrode 130 having a different form than the examples of the piezoelectric actuator 100 in FIGS. 1-3. In the example in FIG. 4, third grooves 132 are formed in the second electrode 130. The third grooves 132 are formed in a first direction (the Y-axis direction in FIG. 4) of the piezoelectric actuator 100.

The third grooves 132 have a third width W3 and a third depth d3. Together with the first grooves 122, the third grooves 132 reduce a height of portions of the piezoelectric actuator 100. For example, the piezoelectric actuator 100 have a height h in portions in which the third grooves 132 are not formed, and have a third height h3 in portions in which the third grooves 132 are formed.

In FIG. 4, a case in which the third grooves 132 are formed at areas symmetrical to those of the first grooves 122 is illustrated. However, positions of the third grooves 132 are not limited to those illustrated in FIG. 4. For example, the third grooves 132 may be formed at areas that are not symmetrical to those of the first grooves 122.

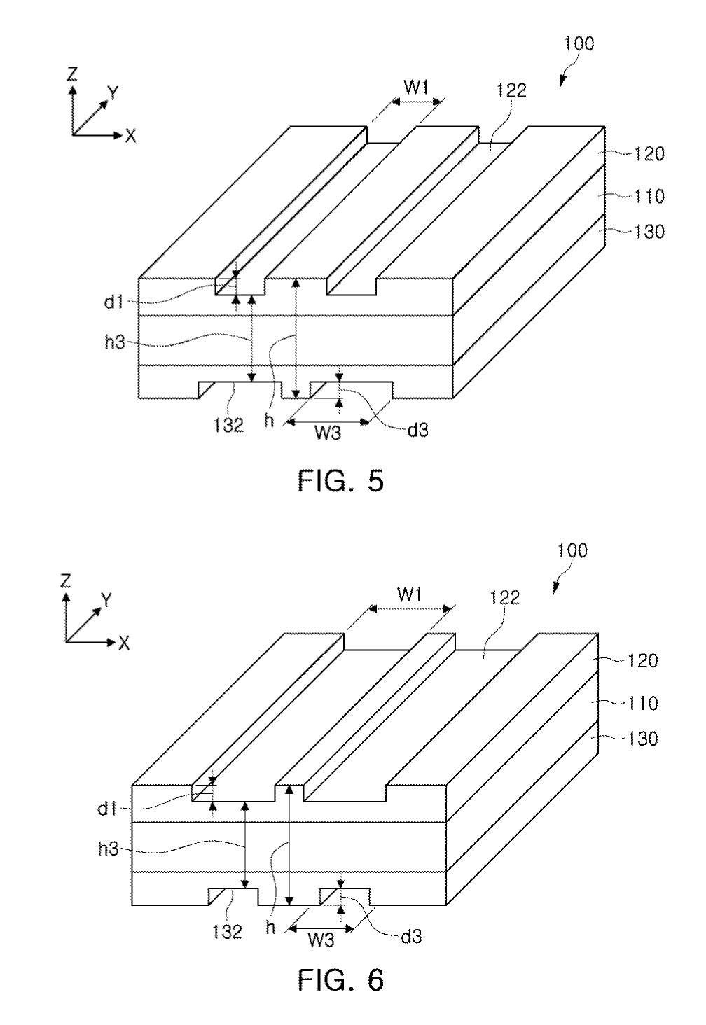

FIG. 5 is a perspective view of a modified form of the third example of the piezoelectric actuator in FIG. 4.

The piezoelectric actuator 100 in FIG. 4 may be modified into a form illustrated in FIG. 5 in which the first and third grooves 122 and 132 have different dimensions. In the example in FIG. 5, a width W3 of the third grooves 132 is larger than a width W1 of the first grooves 122. As another example, a depth d3 of the third grooves 132 may be larger than a depth d1 of the first grooves 122.

FIG. 6 is a perspective view of another modified form of the third example of the piezoelectric actuator in FIG. 4.

The piezoelectric actuator 100 in FIG. 4 may be modified into another form illustrated in FIG. 6 in which the first and third grooves 122 and 132 have different dimensions. In the example in FIG. 6, a width W3 of the third grooves 132 is smaller than a width W1 of the first grooves 122. As another example, a depth d3 of the third grooves 132 may be smaller than a depth d1 of the first grooves 122.

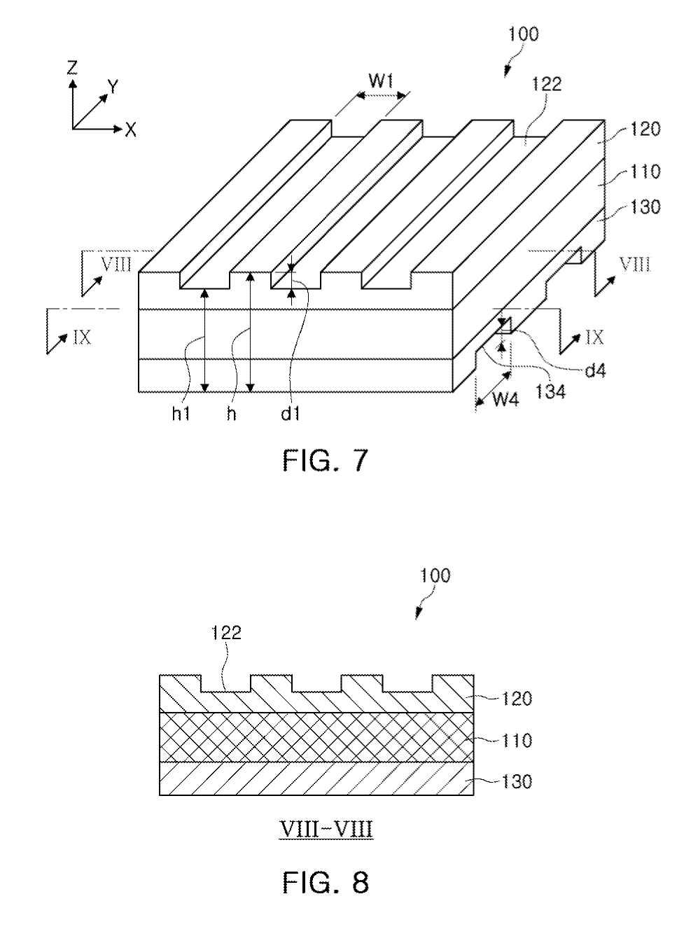

FIG. 7 is a perspective view of a fourth example of a piezoelectric actuator.

A piezoelectric actuator 100 in FIG. 7 has first and second electrodes 120 and 130 having different forms than the examples of the piezoelectric actuator 100 in FIGS. 1-6. In the example in FIG. 7, grooves extending in directions perpendicular to one another are formed in the first and second electrodes 120 and 130.

In the example in FIG. 7, first grooves 122 extending in a first direction (the Y-axis direction in FIG. 7) are formed in the first electrode 120, and fourth grooves 134 extending in a second direction (the X-axis direction in FIG. 7) are formed in the second electrode 130. As another example, first grooves 122 extending in the second direction (the X-axis direction in FIG. 7) may be formed in the first electrode 120, and fourth grooves 134 extending in the first direction (the Y-axis direction in FIG. 7) may be formed in the second electrode 130.

The electrodes 120 and 130 having the structures described above are advantageous in inducing high-temperature heat generation in upper and lower surfaces of the piezoelectric element 110.

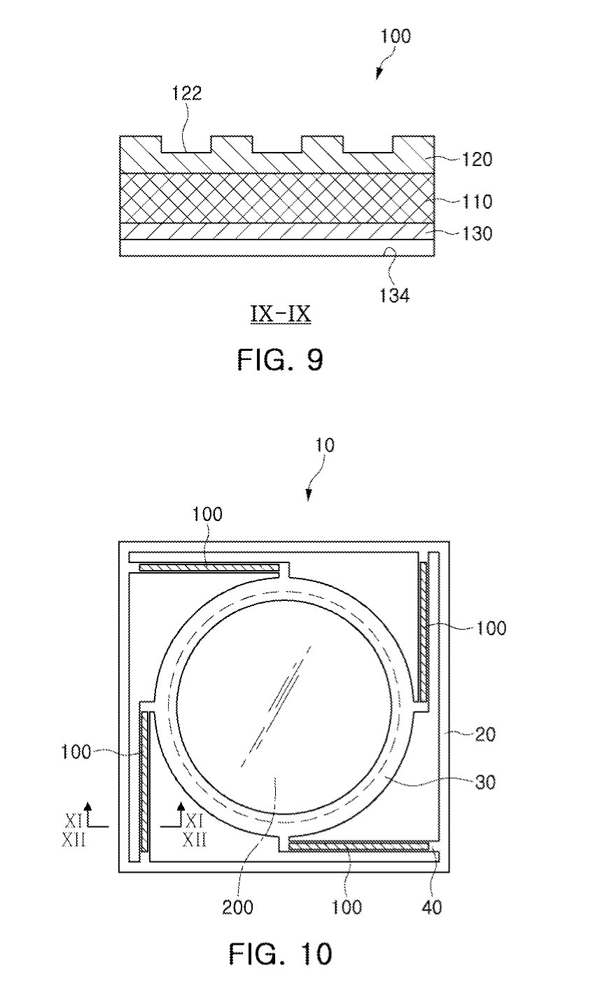

Examples of cross-sectional forms of the example of the piezoelectric actuator 100 in FIG. 7 will be described with reference to FIGS. 8 and 9.

The piezoelectric actuator 100 in FIG. 7 has cross sections having different forms depending on whether or not the fourth grooves 134 are present.

FIG. 8 is a cross-sectional view of the fourth example of the piezoelectric actuator in FIG. 7 taken along the line VIII-VIII in FIG. 7.

Portions of the piezoelectric actuator 100 in FIG. 7 in which the fourth grooves 134 are not formed have a cross section having a form illustrated in FIG. 8. In the cross section having this form, a height of the piezoelectric actuator 100 is reduced in portions in which the first grooves 122 are formed.

FIG. 9 is a cross-sectional view of the fourth example of the piezoelectric actuator 100 in FIG. 7 taken along the line IX-IX in FIG. 7.

Portions of the piezoelectric actuator 100 in FIG. 7 in which the fourth grooves 134 are formed have a cross-sectional form illustrated in FIG. 9. In the cross section having this form, a height of the piezoelectric actuator 100 is reduced in portions in which the first and fourth grooves 122 and 134 are formed. In addition, a height of the piezoelectric actuator 100 is lowest in portions in which the first and fourth grooves 122 and 134 overlap each other as illustrated in FIG. 9.

FIG. 10 is a plan view of an example of a lens module.

A lens module 10 includes a fixed portion 20, a lens support portion 30, and connecting portions 40. In addition, the lens module 10 piezoelectric actuators 100 that may be any of the examples of the piezoelectric actuator 100 described above. In addition, the lens module 10 includes a lens 200.

In the example in FIG. 10, the fixed portion 20 is a quadrangular frame. The fixed portion 20 may be manufactured by a micro-electromechanical systems (MEMS) process. For example, the fixed portion 20 may be manufactured from a wafer.

The lens support portion 30 has a shape coinciding with that of the lens 200. In the example in FIG. 10, the lens support portion 30 has a circular shape. However, a shape of the lens support portion 30 is not limited thereto. For example, in a case in which the lens 200 has a quadrangular shape, the lens support portion 30 may have a quadrangular shape.

The connecting portions 40 connect the fixed portion 20 and the lens support portion 30 to each other. In the example in FIG. 10, the connecting portions 40 extend from one side of the fixed portion 20 to an edge portion of the lens support portion 30. However, the connecting portions 40 are not limited to this form. For example, the connecting portions 40 may extend from one side of the fixed portion 20 to the center of the lens support portion 30.

The fixed portion 20, the lens support portion 30, and the connecting portions 40 may be formed integrally with each other. For example, the fixed portion 20, the lens support portion 30, and the connecting portions 40 may be manufactured by an etching process from a single wafer. This example is advantageous in making the lens module 10 thin.

The piezoelectric actuators 100 are disposed in or on the connecting portions 40. In the example in FIG. 10, one piezoelectric actuator 100 is disposed in or on each of four connecting portions 40. The piezoelectric actuators 100 may be configured to warp the connecting portions 40. For example, the piezoelectric actuators 100 may be configured to apply a driving force to bend the connecting portions 40 upward or downward.

The lens module 10 configured as described above moves the lens 200 depending on the driving force of the piezoelectric actuators 100. For example, the lens module 10 drives a plurality of piezoelectric actuators 100 in the same direction to adjust a focal length of the lens 200. As another example, the lens module 10 drives the plurality of piezoelectric actuators 200 in different directions to correct an inclined state of the lens 200.

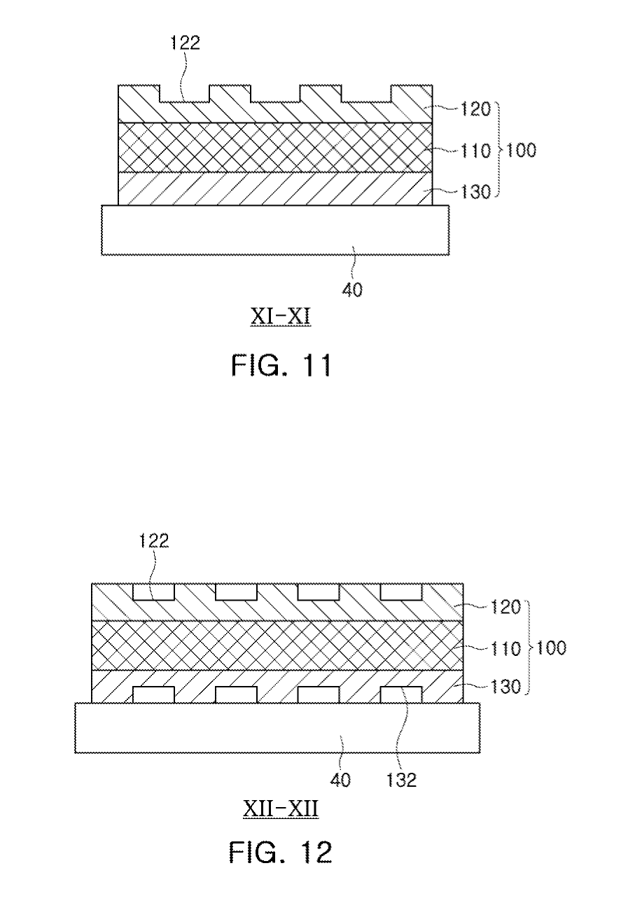

FIG. 11 is an example of a cross-sectional view of the example of the lens module of FIG. 10 taken along the line XI-XI in FIG. 10.

The lens module 10 includes piezoelectric actuators 100 that are capable of performing self-healing. In the example in FIG. 11, in the piezoelectric actuators 100, a plurality of first grooves 122 are formed in a first electrode 120.

FIG. 12 is another example of a cross-sectional view of the example of the lens module of FIG. 10 taken along the line XII-XII in FIG. 10.

The lens module 10 includes piezoelectric actuators 100 that are capable of performing self-healing. In the example in FIG. 12, in the piezoelectric actuators 100, a plurality of first grooves 122 and a plurality of third grooves 132 are formed in first and second electrodes 120 and 130.

The piezoelectric actuators 100 configured as described above are capable of self-healing internal defects due to high-temperature heat generation and phase change phenomena occurring in the portions in which the grooves 122 and 132 are formed as described above.

Therefore, the lens module 10 may precisely focus the lens 200 and correct an inclination of the lens 200 using the piezoelectric actuators 100.

The various examples described above improve a driving reliability of the piezoelectric actuator by enabling self-healing of internal defects.

While this disclosure includes specific examples, it will be apparent to one of ordinary skill in the art that various changes in form and details be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A piezoelectric actuator comprising:
a piezoelectric element;
a first electrode disposed on a first surface of the piezoelectric element; and
a second electrode disposed on a second surface of the piezoelectric element;
wherein one or more first grooves extending in a first direction of the piezoelectric element are formed in the first electrode.

2. The piezoelectric actuator of claim 1, wherein one or more second grooves extending in a second direction of the piezoelectric element are formed in the first electrode.

3. The piezoelectric actuator of claim 2, wherein the first and second grooves have different dimensions.

4. The piezoelectric actuator of claim 1, wherein one or more third grooves extending in the first direction of the piezoelectric element are formed in the second electrode.

5. The piezoelectric actuator of claim 4, wherein the first and third grooves have different dimensions.

6. The piezoelectric actuator of claim 1, wherein one or more fourth grooves extending in a second direction of the piezoelectric element are formed in the second electrode.

7. The piezoelectric actuator of claim 6, wherein the first and fourth grooves have different dimensions.

8. The piezoelectric actuator of claim 1, wherein the piezoelectric element comprises a manganese oxide.

9. A lens module comprising:
a plurality of connecting portions connecting a fixed portion and a lens support portion to each other; and
piezoelectric actuators disposed in or on the plurality of connecting portions and configured to deform the connecting portions to change a position of the lens support portion relative to the fixed portion;
wherein each of the piezoelectric actuators comprises:
a piezoelectric element;
a first electrode disposed on a first surface of the piezoelectric element and in which one or more first grooves extending in a first direction of the piezoelectric element are formed; and
a second electrode disposed on a second surface of the piezoelectric element.

10. The lens module of claim 9, wherein one or more second grooves extending in a second direction of the piezoelectric element are formed in the first electrode.

11. The lens module of claim 10, wherein the first and second grooves have different dimensions.

12. The lens module of claim 9, wherein one or more third grooves extending in the first direction of the piezoelectric element are formed in the second electrode.

13. The lens module of claim 12, wherein the first and third grooves have different dimensions.

14. The lens module of claim 9, wherein one or more fourth grooves extending in a second direction of the piezoelectric element are formed in the second electrode.

15. The lens module of claim 14, wherein the first and fourth grooves have different dimensions.

16. The lens module of claim 9, wherein the piezoelectric element comprises a manganese oxide.

17. A piezoelectric actuator comprising:
a piezoelectric element;
a first electrode disposed on the piezoelectric element; and
a second electrode disposed on the piezoelectric element;
wherein either one or both of the first electrode and the second electrode are configured to cause the piezoelectric actuator to have areas having different current resistance values.

18. The piezoelectric actuator of claim 17, wherein one or more grooves are formed in the either one or both of the first electrode and the second electrode to cause the piezoelectric actuator to have the areas having different current resistance values.

19. The piezoelectric actuator of claim 18, wherein the one or more grooves comprise a plurality of grooves having different dimensions.

20. The piezoelectric actuator of claim 18, wherein the one or more grooves comprise a plurality of grooves extending in different directions of the piezoelectric actuator.
